(19) United States
(12) Patent Application Publication
(10) Pub. No.: US 2013/0192867 A1
(43) Pub. Date: Aug. 1, 2013

(54) WEATHERPROOF OUTLET COVER ASSEMBLY

(71) Applicant: Andrew Greaney, Buffalo Grove, IL (US)

(72) Inventor: Andrew Greaney, Buffalo Grove, IL (US)

(21) Appl. No.: 13/362,989

(22) Filed: Jan. 31, 2012

(51) Int. Cl. H05K 5/03; B23P 11/02

(52) U.S. Cl. 174/66; 29/453

(57) ABSTRACT

An outlet cover assembly includes a base member configured to be mounted to a surface and a cover member pivotally connected to the base member via a pair of tabs with openings configured to engage a complementary pair of pins on the base member. The cover member and base member are configured to facilitate attachment of the cover member to the base member without substantial deformation of the pair of tabs when an angle formed between a major axis of the cover member and a major axis of the base member is greater than about 90 degrees. The cover member is secured to the base member when the angle formed between the cover member and base member is less than 90 degrees.

### FIELD

This application relates to outlet covers. Specifically, this application relates to a weatherproof outlet cover assembly with a user attachable cover member.

### BACKGROUND

An outlet cover assembly is a housing that enclose a wiring devices, such as AC voltage terminals, switches, etc. The outlet cover assembly helps protect against short circuits, electrical shock, and/or unwanted use of the wiring device. The outlet cover assembly usually includes a base member that mounts to a surface and a cover member. The base member defines one or more center openings through which the device is accessed and fastener openings through which fasteners are inserted and threaded to secure the base member to a surface.

The cover member is configured to be opened to facilitate access to the device, or closed to prevent access to the device and protect the device from the elements. Typical cover members are fixed to the base in the factory.

To mount the outlet cover assembly, an installer positions the assembly over a pre-installed electrical terminal, holds the cover member in the open position, inserts fasteners through the fastener openings, and then tightens the fasteners. However, holding the cover member while fastening can tend to be a cumbersome process. The process is exacerbated when the wiring device is close to the ground as the cover member tends to block the view of the inside of the outlet cover assembly, making it difficult to thread the fasteners.

Another problem with existing outlet covers assemblies relates to extra-duty requirement UL 514D in the National Electric Code (NEC) that requires cover members of outlet cover assemblies to withstand a force of 40 pounds without breaking off. Some hinges used on outlet cover assemblies may tend to permanently deform or break under such a force.

### SUMMARY

In one aspect, an outlet cover assembly includes a base member configured to be mounted to a surface and a cover member pivotally connected to the base member via a pair of tabs with openings configured to engage a complementary pair of pins on the base member. The cover member and the base member are configured to facilitate attachment of the cover member to the base member without substantial deformation of the pair of tabs when an angle formed between a major axis of the cover member and a major axis of the base member is greater than about 90 degrees. The cover member is secured to the base member when the angle formed between the cover member and the base member is less than 90 degrees.

In a second aspect, an outlet cover assembly includes a base member and a cover member. The base member includes a pair of opposing sidewalls, top and bottom opposing sidewalls extending therebetween, and a rear wall. First and second pins extend from respective outside surfaces of the pair of sidewalls. The cover member is configured to be attached to the base member. The cover member includes first and second tabs positioned at a top end of the cover member that extend, respectively, from opposing edges of the cover member. Each tab defines an opening configured to slide over and to engage one of the first and second pins of the base member. A thickness of the cover member is configured so that during attachment of the cover member to the base member, the second tab flexes by an amount less than about 0.05 inches, as measured by a change in distance between the first and second tabs.

Yet another aspect is to provide a method of assembling an outlet cover assembly that includes providing a base member. The base member includes a pair of opposing sidewalls, top and bottom opposing sidewalls extending therebetween, and a rear wall. First and second pins extend from respective outside surfaces of the pair of sidewalls. A cover member is also provided. The cover member includes first and second tabs positioned at a top end of the cover member that extend, respectively, from opposing edges of the cover member. Each tab defines an opening configured to slide over and to engage one of the first and second pins of the base member. The cover member is rotated in a first direction relative to the base member to facilitate sliding of the first pad over the first pin to secure the first pad to the first pin. The cover is then rotated in an opposite direction while the first pad is secured to the first pin to secure the second pad to the second pin. While securing the second pad to the second pin, the second tab flexes by an amount less than about 0.05 inches, as measured by a change in distance between the first and second tabs.

### BRIEF DESCRIPTION OF THE DRAWINGS

The accompanying drawings are included to provide a further understanding of the claims and are incorporated in and constitute a part of this specification.

FIGS. 1A and 1B are front and back perspective views, respectively, of an exemplary outlet cover assembly in a closed configuration;

FIGS. 2A and 2B are front and back perspective views, respectively, of the outlet cover assembly in an open configuration;

FIG. 3 illustrates the outlet cover assembly fixed to a surface;

FIG. 4 illustrates a pin of a base member of the outlet cover assembly;

FIG. 5 illustrates a tab of a cover member of the outlet cover assembly;

FIG. 6 is a top view of the outlet cover assembly;

FIG. 7 illustrates a space between the tab of the cover member and the base member; and

FIGS. 8A and 8B illustrate attachment of the cover member to the base member.

### DETAILED DESCRIPTION

Embodiments below describe an outlet cover assembly with a cover member pivotally attached to a base member. The base member is configured to be mounted over a wiring device and secured to a surface. The cover member rotates between open and closed positions. In the open position, the cover member is attachable to the base member. In the closed position, the cover member is secured to the base member.

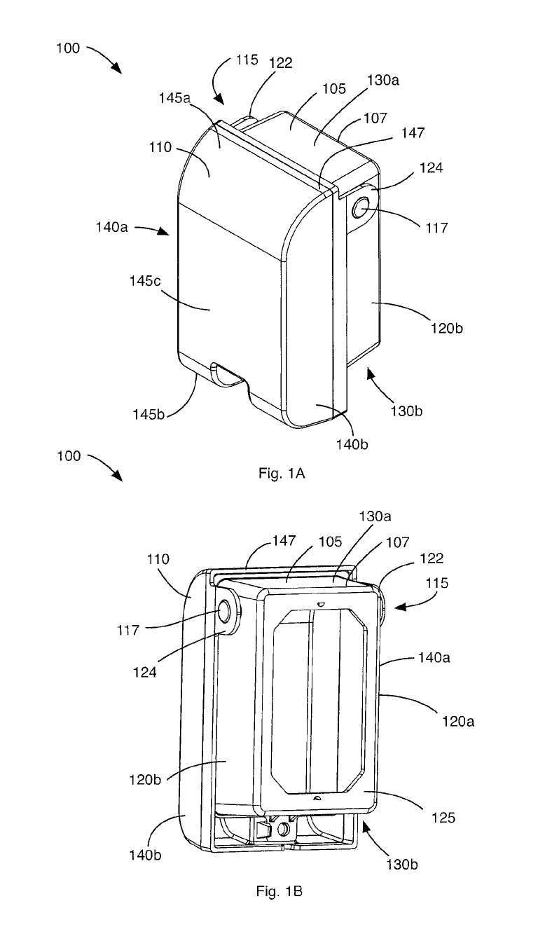

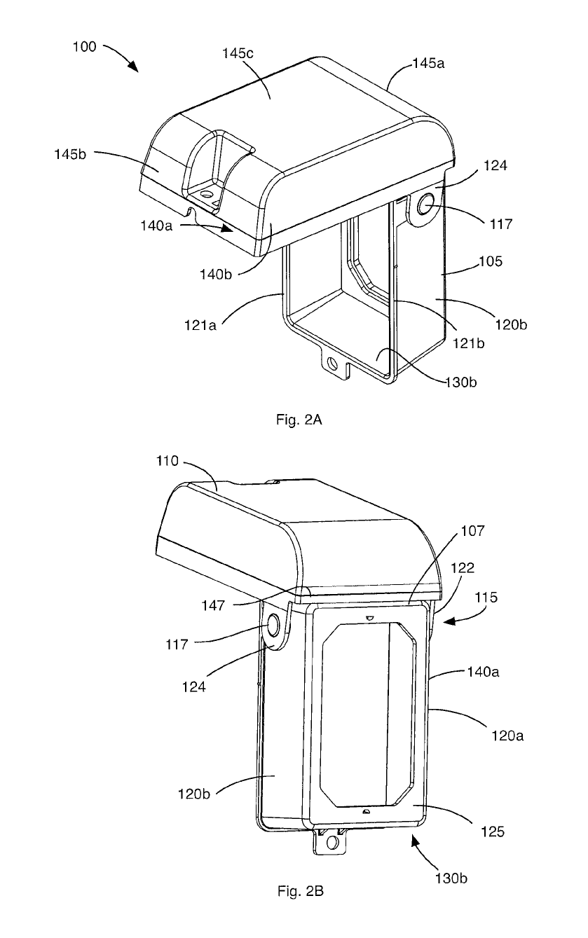

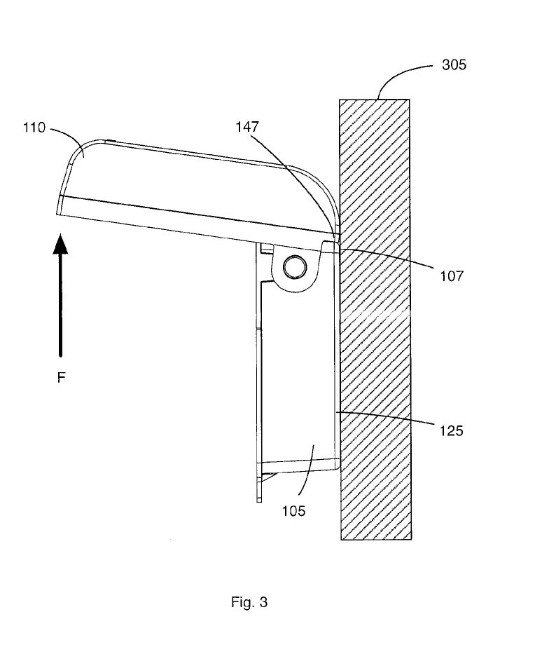

FIGS. 1A and 1B are front and back perspective views, respectively, of an exemplary outlet cover assembly 100 in a close configuration. The outlet cover assembly 100 includes a base member 105 and a cover member 110. The cover member 110 is configured to pivotally rotate to an open configuration, as illustrated in FIGS. 2A and 2B. The base member 105 and cover member 110 may be formed of a rigid material, such as aluminum or steel. The gauge/thickness of the material may be about 0.10 inch. In some implementations, the base member 105 and cover member 110 may be formed from different materials and/or have different gauges/thicknesses.

The base member 105 is a generally open box-shaped structure that includes a pair of opposing sidewalls (120a, 120b). Top and bottom (130a, 130b) opposing sidewalls extend between the top edges and bottom edges, respectively, of the sidewalls (120a,120b). A rear wall 125 extends between the edges of the respective sidewalls (120a, 120b, 130a, 130b). The rear wall 125 may define an opening through which a wiring device may be accessed. While a single rectangular opening is shown, it is understood that the number opening and/or shape may be different depending on the type of outlet terminal being covered.

First and second pins (115, 117) extend from outside surfaces of the pair of sidewalls (120a, 120b), respectively. In some implementations the first and second pins (115, 117) are integrally formed with the base member 105 and have a generally cylindrical shape with a diameter D1 of about 0.5 inches. The position of the longitudinal centers of the pins (115, 117) may be offset from the top sidewall 130a and rear wall 125 by about 1 inch and 0.6 inches, respectively. In some implementations, the pins (115, 117) are centered between front and back edges of the respective sidewalls (120a, 120b).

The diameter of the pins (115, 117) and relative positioning of the pins (115, 117) along the sidewalls allows the pins (115, 117) to withstand the forces associated with the extra-duty requirement, described earlier. For example, as illustrated in FIG. 3, when mounted to a surface 305, the pins (115, 117) are configured to stay intact when the cover member 110 is pulled in an upward direction with a force F of up to about 40 pounds. Smaller diameter pins may shear under such a force. And positioning of the pins (115, 117) closer to the edges of the sidewalls (120a, 120b) may cause the sidewalls (120a, 120b) to crack under such a force.

In addition, in the open configuration, the top edge 147 of the cover member 110 is configured to contact the top edge 107 of the rear wall 125. Thus, the upward force F is translated to the rear wall 125, which secured to the surface and, therefore, able to withstand the force. Contact of the top edge 107 of the cover member 110 with the rear wall 125 also limits the amount by which the cover member 110 may be opened. In one implementation, contact occurs when the cover member 110 forms an angle of about 110 degrees with the base member 105. This places the center of gravity of the cover member 110 beyond the front of the base member 105 so that that cover member 110 will automatically close under the force of gravity.

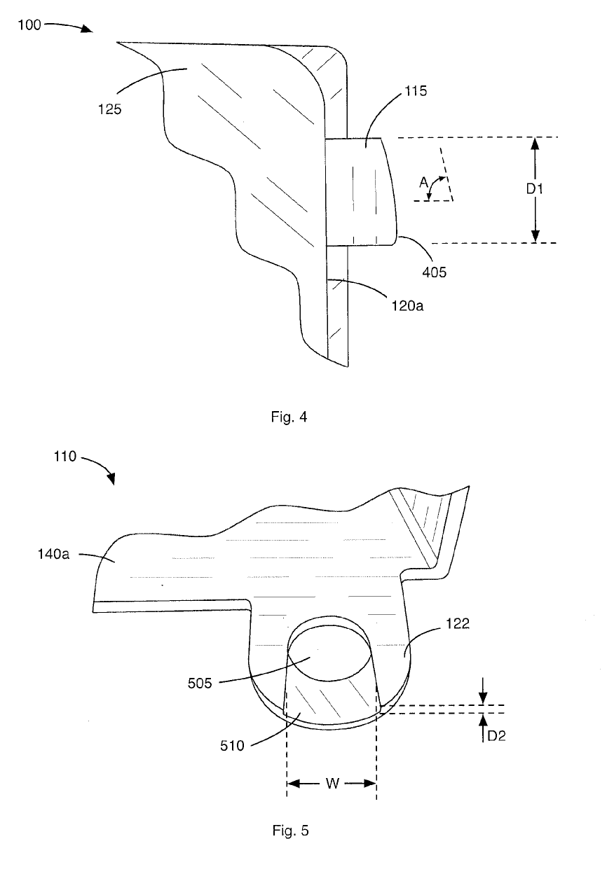

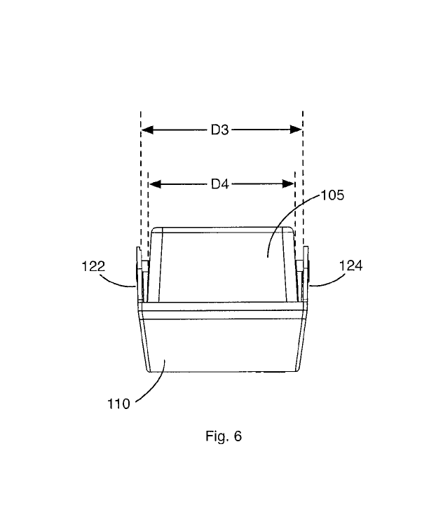

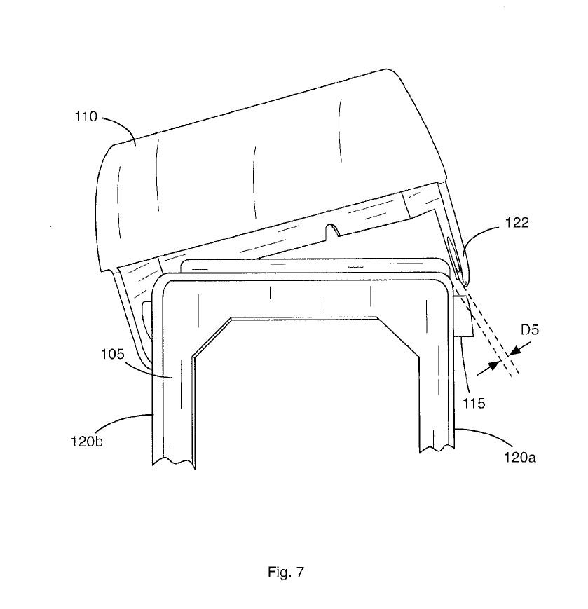

In FIG. 4, a first pin 115 may have a beveled outside face 405. The angle A formed between the surface of the outside face 405 and the longitudinal axis of the first pin 115 may be about 83 degrees. The angle of the bevel is configured so that during attachment of the cover member 110 to the base member 105, the surface of the outside face of the first pin 115 is substantially parallel to the surface of the first tab 122 when an edge of the first tab 112 reaches an edge of the outside face 405 of the first pin 117, as illustrated in FIG. 6C.

Referring back to FIGS. 1A and 1B, the cover member 110 is a generally box-shaped structure that includes a pair of opposing sidewalls 140a and 140b, and a front surface that includes upper, lower, and center surfaces (145a, 145b, 145c) that extend between forward facing edges of the sidewalls (140a, 140b).

A first tab and a second tab (122, 124) extend from rear edges of the pair of sidewalls (140a, 140b), respectively, and are positioned near the upper surface 145a of the cover member 110. Each tab (122, 124) defines an opening 505 (FIG. 3) configured to slide over and to engage one of the first and second pins (115, 117) of the base member 105. The opening 505 is more clearly illustrated in FIG. 5

In FIG. 5, the first tab 122 defines a channel 510 sized to receive the first pin 115. The width W of the channel 510 may be slightly larger than the diameter D1 of the pin 115. The channel 510 extends from an edge of the first tab 122 to the opening 505 of the first tab 122. The depth of the channel 510 decreases gradually from a depth D2 of about 0.035 inches at the edge of the first tab 122 to a depth of about zero inches at the opening in the first tab 122.

In FIG. 6, the distance D3 between the first and second tabs (122, 124) is about 0.375″ inches larger than the distance between the forward edges (121a, 121b) of the pair of opposing sidewalls (120a, 120b) of the base member 105. This small difference facilitates rotation of the cover member 110 about the pins (115, 117). Maintaining a small difference also prevents removal of the cover member 110 from the base member 105 when the outlet cover assembly 100 is in a closed configuration because the first and second tabs (122, 124) will interfere with the forward edges (121a, 121b) of the pair of opposing sidewalls (120a, 120b) if removal is attempted.

The distance D4 between the opposing sidewalls (120a, 120b) in a region nearest the first and second pins (115, 117) is about 0.375 inches smaller than the distance between the first and second tabs (122, 124). Referring to FIG. 7, this difference in distances results in a space with a width D5 of about 0.10 inches between the first tab 122 and the sidewall 120a when the outlet cover assembly 100 is in the open configuration. This space allows the first tab 122 to clear the sidewall 120a without interference, which facilitates attachment of the cover member 110 to the base member 105.

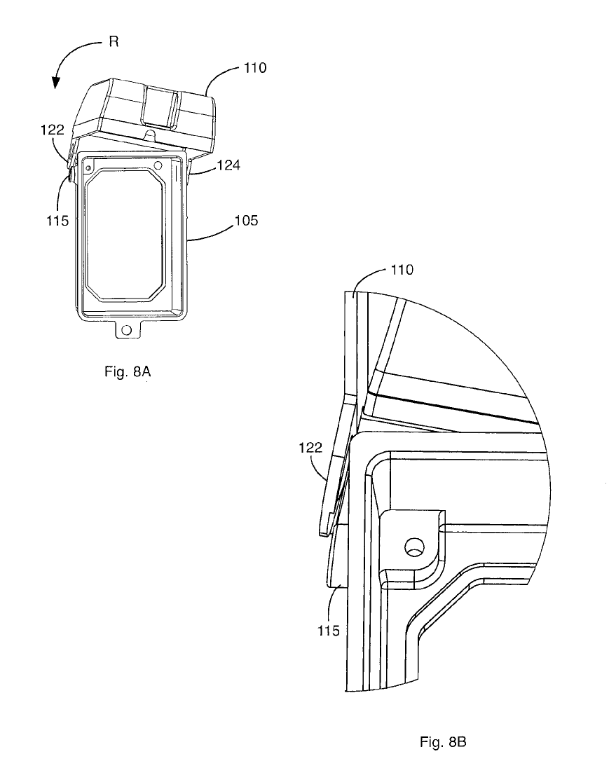

FIGS. 8A and 8B illustrate attachment of the cover member 110 to the base member 105. In FIG. 8A, the second tab 124 of the cover member 110 is slid over the second pin 117 of the base member 105 and rotated in a direction R. As illustrated in FIG. 8B, rotation of the cover member 110 brings the first tab 122 in proximity of the first pin 115. Just before contact, the outside face of the pin 115 is substantially parallel to the surface of the tab 122 and acts as a ramp that allows the tab 122 to easily slide over the outside face of the pin 115. As rotation continues, the pin 115 is guided into the opening in the first tab 122 by the channel 510. The gradual change in the depth of the channel 510 causes the first pin 115 to press against the first tab 122, which in turn cause the first tab 115 to resiliently flex by a small amount during rotation. The amount of flex may be specified in terms of the change in the distance D3 (FIG. 6) between the first and second tabs (122,124). In this case, the flex is about 0.05 inches. The gradual change in depth of the channel and the substantially parallel surfaces facilitates flexing of the relatively rigid material.

While the outlet cover assembly has been described with reference to certain dimensions, materials and configurations, it will be understood by those skilled in the art that various changes may be made and equivalents may be substituted without departing from the scope of the claims. For example, the various dimensions above may be scaled up or down as needed to accommodate a wiring devices of different sizes. The pins may be provided on the cover and the tabs may be provided on the base member. The pins may be positioned on inside surfaces of the base member rather than on outside surfaces and the tabs on the cover member may be configured to engage the inward facing pins. Either pin or both pins may be beveled. Either tab or both tabs may have channels. Many other modifications may be made to adapt a particular situation or material to the teachings without departing from its scope. Therefore, it is intended that the outlet cover assembly defined by the claims not be limited to the particular embodiment disclosed, but rather any outlet cover assembly that falls within the scope of the claims.

I claim:

1. An outlet cover assembly comprising:
a base member configured to be mounted to a surface; and
a cover member pivotally connected to the base member via a pair of tabs with openings configured to engage a complementary pair of pins on the base member, wherein the cover member and base member are configured to facilitate attachment of the cover member to the base member without substantial deformation of the pair of tabs when an angle formed between a major axis of the cover member and a major axis of the base member is greater than about 90 degrees and secured to the base member when the angle is less than 90 degrees.

2. The outlet cover assembly according to claim 1, wherein in a fully open configuration, a top edge of the cover assembly is in contact with a top edge of the base member.

3. The outlet cover assembly according to claim 2, wherein when the cover assembly is mounted in a vertical position and is in the fully open configuration, a center of gravity of the cover member is beyond the cover member so that the cover member closes automatically under a force of gravity.

4. The outlet cover assembly according to claim 3, wherein when the outlet cover assembly is mounted to the surface, and the cover member is in a fully open configuration, the cover member is configured to support an upward vertical force at a bottom edge of about 40 pounds without separation from the base member.

5. An outlet cover assembly comprising:
a base member that includes:
a pair of opposing sidewalls, top and bottom opposing sidewalls extending therebetween, and a rear wall; and
first and second pins that extend from respective outside surfaces of the pair of sidewalls; and
a cover member configured to be attached to the base member that includes:
first and second tabs positioned at a top end of the cover member that extend, respectively, from opposing edges of the cover member, wherein each tab defines an opening configured to slide over and to engage one of the first and second pins of the base member, wherein a thickness of the cover member is configured so that during attachment of the cover member to the base member, the second tab flexes by an amount less than about 0.05 inches, as measured by a change in distance between the first and second tabs.

6. The outlet cover assembly according to claim 1, wherein the first and second pins are integrally formed with the base member and have a generally cylindrical shape with a diameter of about 0.5 inches.

7. The outlet cover assembly according to claim 1, wherein the cover member comprises a metal material with a gauge/thickness of about 0.10 inches.

8. The outlet cover assembly according to claim 1, wherein an outside face of the first pin is beveled.

9. The outlet cover assembly according to claim 8, wherein a surface plane of the outside face forms an angle of 83 degrees with a longitudinal axis of the first pin.

10. The outlet cover assembly according to claim 9, wherein the angle is configured so that during attachment of the cover member to the base member, the outside face of the first pin is substantially parallel to a surface of the first tab when an edge of the first tab reaches an edge of the outside face of the first pin.

11. The outlet cover assembly according to claim 1, wherein a first tab defines a channel that extends from an edge of the first tab to the opening of the first tab for receiving the first pin.

12. The outlet cover assembly according to claim 5, wherein a depth of the channel decreases gradually from a depth of about 0.035 inches at the edge of the first tab to a depth of about zero inches at the opening in the first tab.

13. The outlet cover assembly according to claim 5, wherein the distance between the first and second tabs substantially matches a distance between forward edges of the pair of opposing sidewalls, which thereby prevents removal of the cover member when the cover assembly is in a closed configuration.

14. The outlet cover assembly according to claim 5, wherein the distance between the first and second tabs is greater than a distance between top edges of the pair of opposing sidewalls by about 0.375 inches to thereby allow attachment of the cover member when the cover assembly is in an open configuration.

15. The outlet cover assembly according to claim 5, wherein the rear wall defines an opening sized to facilitate access to an outlet terminal.

16. A method of assembling an outlet cover assembly comprises:
providing a base member that includes:
a pair of opposing sidewalls, top and bottom opposing sidewalls extending therebetween, and a rear wall; and
first and second pins that extend from respective outside surfaces of the pair of sidewalls; and
providing a cover member that includes:
first and second tabs positioned at a top end of the cover member that extend, respectively, from opposing edges of the cover member, wherein each tab defines an opening configured to slide over and to engage one of the first and second pins of the base member;
rotating the cover member in a first direction relative to the base member;
sliding the first pad over the first pin to secure the first pad to the first pin; and
rotating the cover member in an opposite direction while the first pad is secured to the first pin to secure the second pad to the second pin, wherein while securing the second pad to the second pin, the second tab flexes by an amount less than about 0.05 inches as measured by a change in distance between the first and second tabs.

17. The method according to claim 16, wherein the first and second pins are integrally formed with the base member and have a generally cylindrical shape with a diameter of about 0.5 inches.

18. The method according to claim 16, wherein the cover member comprises a metal material with a gauge/thickness of about 0.10 inches.

19. The method according to claim 16, wherein an outside face of the first pin is beveled.

20. The method according to claim 19, wherein a surface plane of the outside face forms an angle of 83 degrees with a longitudinal axis of the first pin.
